(19) United States
(12) Patent Application Publication
(10) Pub. No.: US 2014/0342488 A1
(43) Pub. Date: Nov. 20, 2014

(54) Preparation Method of Manufacturing Thermoelectric Nanowires Having Core/Shell Structure

(71) Applicants: Woo Young Lee, Seoul (KR); Joo Hoon Kang, Seoul (KR); Jong Wook Roh, Yongin-si (KR); Woo Young Shim, Seoul (KR)

(72) Inventors: Woo Young Lee, Seoul (KR); Joo Hoon Kang, Seoul (KR); Jong Wook Roh, Yongin-si (KR); Woo Young Shim, Seoul (KR)

(73) Assignee: Industry-Academic Cooperation Foundation, Younsei University, Seoul (KR)

(21) Appl. No.: 14/360,004

(22) PCT Filed: Apr. 5, 2012
(86) PCT No.: PCT/KR2012/002566

§ 371 Date: May 22, 2014

(30) Foreign Application Priority Data
Nov. 24, 2011 (KR) 10-2011-0123806

(51) Int. Cl. H01L 35/34; H01L 35/04; H01L 35/16; H01L 35/18; C30B 1/04; C30B 23/08

(52) U.S. Cl. CPC H01L 35/34; C30B 1/04; C30B 23/08; H01L 35/16; H01L 35/18; H01L 35/04
USPC 438/54

(57) ABSTRACT

Disclosed is a preparation method of manufacturing a thermoelectric nanowire having a core/shell structure. The preparation method of thermoelectric nanowire includes preparing a substrate provided with an oxide layer formed thereon, and forming a Bi thin film on the oxide layer, heat treating a structure produced during forming the Bi thin film to induce compressive stress due to differences in coefficients of thermal expansion between the substrate, the oxide layer and the Bi thin film, to grow a Bi single crystal nanowire on the Bi thin film, and cooling the substrate of a structure on which the nanowire is grown to a low temperature, and sputtering a thermoelectric material on the Bi single crystal nanowire in a cooled state to manufacture a thermoelectric nanowire having a core/shell structure of Bi/thermoelectric material.

### TECHNICAL FIELD

The present invention relates to a method of manufacturing a thermoelectric nanowire, and more particularly, to a method of manufacturing a thermoelectric nanowire having a core/shell structure including a bismuth (Bi) nanowire as a core and a thermoelectric material as a shell.

### BACKGROUND ART

In general, semimetals, such as bismuth (Bi), antimony (Sb), arsenic (As), silicon (Si), and germanium (Ge), have properties common to both metals and nonmetals, and are commonly used in electric device components as single compound or an alloy. Particularly, semimetals alloyed with semiconductors have received a great deal of attention as thermoelectric materials.

A thermoelectric material is a material having a low degree of thermal conductivity and a high degree of electrical conductivity, and in-depth research into thermoelectric materials is currently being conducted. For example, since an alloy of Bi and tellurium (Te), BiₓTe₁₋ₓ has a relatively large mass and has a small spring constant, due to Van der Waals bonding between Bi and Te and covalent bonding between Te atoms, the thermal conductivity thereof may be decreased. Thus, the figure of merit (ZT), exhibiting the thermoelectric efficiency of the thermoelectric material may be increased, and so, BiₓTe₁₋ₓ is currently in common use as a thermoelectric material.

In addition, by manufacturing a thermoelectric nanowire from such a BiₓTe_{1 x} alloy, the electrical density of states may be controlled, and the Seebeck coefficient affecting the thermoelectric effect may be controlled by matching the shape and the peak position of the function of the electrical density of states with a Fermi level. In addition, the movement of electrons may be increased by the quantum confinement effect, and thus, electrical conductivity may be maintained at a high level. Thus, the limit of the thermoelectric material in a bulk phase may be overcome, and a relatively high ZT value may be obtained.

To obtain a high degree of thermoelectric efficiency, the manufacturing of a single crystal thermoelectric nanowire is necessary. However, when considering the inherent properties of the general thermoelectric materials, it may be somewhat difficult to grow a single crystal structure therein. Therefore, the growth of thermoelectric nanowires may be somewhat restricted, and growth methods for the single crystal thermoelectric nanowires have not been commonly known to date.

Generally, it is necessary to grow thermoelectric nanowires from an alloy rather than a single material, and so, a method of growth employing a solvent in which respective materials are dissolved is mainly used. This method includes a template-assisted method, a solution-phase method, a pressure injection method, and the like.

However, according to the template-assisted method, the preparation of a template is not easy. According to other methods, a relatively complicated process including the preparation of a starting material, etc. is necessary. In addition, the removal of an appropriate template and the removal of remaining chemical materials from the surface of a nanowire are necessary for conducting a single nanowire device process. Further, the formation of various patterns during the manufacturing of a device is difficult due to a low aspect ratio. Particularly, since a thermoelectric nanowire grown using a common method has polycrystallinity, thermoelectric efficiency is low, and the observation of the inherent properties of the single crystal thermoelectric nanowire is limited.

Along with the development of nano technology in the late 1990s, research into thermoelectric applications has been actively undertaken. The theoretical background of such research has shown that a thermoelectric figure of merit (ZT) that has reached the limit thereof may be increased in the case that Bi₂Te₃, known as the most appropriate material among bulk state materials for thermoelectric applications, is manufactured on the nanoscale level. However, the thermoelectric figure of merit obtained by using a single thin film or a nanowire is still a considerable distance from being commercially viable. Rather, a high thermoelectric figure of merit was measured in a thermoelectric application using a hetero structure such as a 2D ultra lattice thin film. Venkatasubramanian's group has reported the manufacturing of a 2D ultra lattice thin film in which a high thermoelectric figure of merit of 2.4 was obtained.

However, the group that measured a thermoelectric figure of merit by manufacturing a heterostructure nanowire, that is, a core/shell nanowire structure and by using a single nanowire was not present until now. Since the synthesis of a core/shell structure by using a general method of synthesizing a nanowire is relatively difficult, groups corresponding to masters in thermoelectric field also merely analyzed mechanisms using computer simulations.

### DISCLOSURE

### Technical Problem

An aspect of the present invention provides a method of manufacturing a thermoelectric nanowire having a core/shell structure of Bi/thermoelectric material through manufacturing a single nanowire and sputtering a thermoelectric material.

Particularly, another aspect of the present invention provides a method of manufacturing a thermoelectric nanowire having a core/shell structure having a desired degree of thermal conductivity by controlling interface roughness between a core and a shell of the thermoelectric nanowire having the core/shell structure.

### Technical Solution

According to an aspect of the present invention, there is provided a method of manufacturing a thermoelectric nanowire having a core/shell structure including preparing a substrate provided with an oxide layer formed thereon, and forming a Bi thin film on the oxide layer; heat treating a structure produced during forming the Bi thin film to induce compressive stress due to differences in coefficients of thermal expansion between the substrate, the oxide layer and the Bi thin film, to grow a Bi single crystal nanowire on the Bi thin film; and cooling the substrate of a structure on which the nanowire is grown to a low temperature, and sputtering a thermoelectric material on the Bi single crystal nanowire in a cooled state to manufacture a thermoelectric nanowire having a core/shell structure of Bi/thermoelectric material.

In an embodiment of the present invention, the manufacturing of the thermoelectric nanowire may include controlling roughness of an interface between the Bi single crystal nanowire and the thermoelectric material by controlling the temperature for cooling the substrate.

In an embodiment of the present invention, the cooling to a low temperature may be performed by using liquid nitrogen.

In an embodiment of the present invention, the forming of the Bi thin film may include forming the Bi thin film on the oxide layer in the cooled state using a sputtering method.

In an embodiment of the present invention, the thermoelectric material may be one selected from Te, Bi₂Te₃, PbTe, Sb and S.

In an embodiment of the present invention, the thickness of the shell, a thermoelectric material layer composing the thermoelectric nanowire may be may be equal to half the diameter of the Bi single crystal nanowire.

In an embodiment of the present invention, the single crystal Bi nanowire may have a diameter of 50 to 1,000 nm.

In an embodiment of the present invention, the oxide layer may be at least one selected from the group consisting of SiO₂, BeO, and Mg₂Al₄Si₅O₁₈.

In an embodiment of the present invention, the heat treating temperature may be 200 to 270° C.

In an embodiment of the present invention, the method may further include final heat treating of the core/shell thermoelectric nanowire thus manufactured in the manufacturing operation of the thermoelectric nanowire. In an embodiment of the present invention, a temperature of the final heat treating may be selected from a temperature less than or equal to a melting point of Bi, or a temperature greater than or equal to a melting point of Bi to a temperature less than or equal to a melting point of the thermoelectric material.

### Advantageous Effects

As described above, a single crystal core/shell nanowire may be synthesized without difficulty. In addition, the nanowire may be synthesized without a separate template or a catalyst, and a core/shell nanowire based on a Bi nanowire may be synthesized by using various thermoelectric materials.

Further, the thermal conductivity of a thermoelectric nanowire manufactured by the method of the present invention may be determined by controlling the roughness of the interface of a core and a shell. Thus, a nanowire satisfying requirements required in various fields may be manufactured.

Further, a tube structure of various thermoelectric materials may be synthesized, and the observation of the physical properties of various novel materials such as thermoelectric properties and magnetic Kondo effect, may be helpful in the case when using the tube structure of the nanowire.

### DESCRIPTION OF DRAWINGS

The above and other aspects, features and other advantages of the present invention will be more clearly understood from the following detailed description taken in conjunction with the accompanying drawings, in which:

FIGS. 1A to 1D illustrate a process of manufacturing a thermoelectric nanowire having a core/shell structure according to an embodiment of the present invention;

FIG. 2 is a schematic diagram illustrating a heat treating reactor used for growing a single crystal Bi nanowire according to an embodiment of the present invention;

FIGS. 3A and 3B are schematic diagrams comparing a nanowire having a core/shell structure obtained by performing a low temperature cooling process using liquid nitrogen and a nanowire having a core/shell structure obtained without performing a low temperature cooling process;

FIG. 4A illustrates TEM photographic images of thermoelectric nanowires having a core/shell structure manufactured by an embodiment of the present invention;

FIG. 4B illustrates TEM photographic images of thermoelectric nanowires having a core/shell structure manufactured by another embodiment of the present invention;

FIG. 5 is a graph illustrating thermal conductivities of thermoelectric nanowires having a core/shell structure manufactured by various embodiments of the present invention;

FIG. 6 illustrates SEM and TEM photographic images of a thermoelectric nanowire manufactured by an embodiment of the present invention;

FIG. 7 illustrates TEM photographic images of a thermoelectric nanowire manufactured by an embodiment of the present invention and element mapping images of the nanowire;

FIG. 8 is a graph illustrating a line scanning image of the cross section of a thermoelectric nanowire;

FIG. 9 illustrates a TEM photographic image of a thermoelectric nanowire manufactured by another embodiment of the present invention;

FIG. 10 is a graph illustrating a line scanning image of the cross section of the thermoelectric nanowire in FIG. 9; and

FIG. 11 is a SEM photographic image of a thermoelectric nanowire manufactured by further another embodiment of the present invention.

### BEST MODE

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In addition, the terminology used herein is for the purpose of describing particular example embodiments only and is not intended to limit the present inventive concept. It will be further understood that terms should be interpreted as having a meaning that is consistent with their meaning in the context of the relevant art and will not be interpreted in an idealized or overly formal sense unless expressly so defined herein.

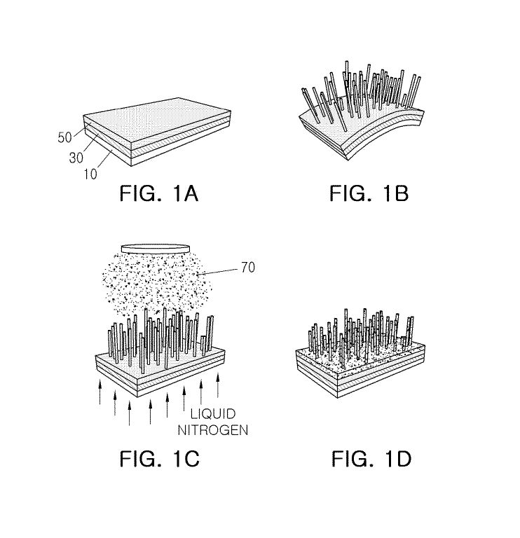

FIGS. 1A to 1D illustrate a process of manufacturing a thermoelectric nanowire having a core/shell structure according to an embodiment of the present invention.

First, as shown in FIG. 1A, according to an embodiment of the present invention, a substrate 10 provided with an oxide layer 30 formed on one side of the substrate 10 is provided. On the oxide layer 30, a Bi thin film 50 is formed. In an embodiment of the present invention, the substrate 10 may be a silicon substrate, and the oxide layer 30 may be at least one oxide layer selected from the group consisting of SiO₂, BeO, and Mg₂Al₄Si₅O₁₈. Preferably, the thickness of the oxide layer 30 may be 3,000 to 5,000 Å.

In an embodiment of the present invention, the Bi thin film 50 may be formed on the oxide layer 30. The Bi thin film may be effectively manufactured by a commonly known sputtering method. For example, the Bi thin film 50 may be formed on the oxide layer 30 by a radio frequency (RF) magnetron sputtering method under a pressure of 4×10⁻⁸ torr at a rate of 32.7 Å/s. Particularly, the substrate 10 may be cooled using liquid nitrogen during forming the Bi thin film 50. The cooling process is performed to form small particle tissues to decrease the diameter of a Bi nanowire to be formed in a following process.

In an embodiment of the present invention, the Bi thin film 50 is preferably formed as a single crystal thin film. Generally, when the Bi thin film is a single crystal layer, the orientation of (003), (006), and (009) in an X-ray diffraction pattern may be obtained.

In addition, the preferable thickness of the Bi thin film 50 may be from 50 nm to 4 μm in an embodiment of the present invention.

After that, in an embodiment of the present invention, as shown in FIG. 1B, the structure thus produced in FIG. 1A is heat treated to grow a Bi single crystal nanowire on the Bi thin film 50 by inducing compressive stress due to the difference of the coefficient of thermal expansion of the substrate 10, the oxide layer 30 and the Bi thin film 50. More particularly, a structure provided with the Bi thin film 50 formed thereon is piled up in a reactor and heat treated to induce the compressive stress and to grow a single crystal Bi nanowire.

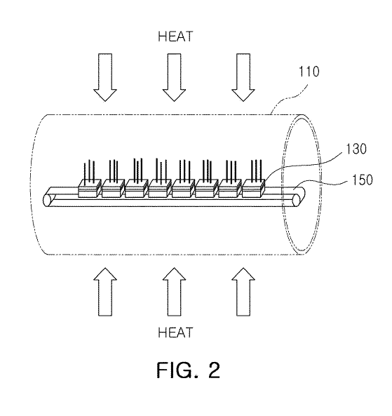

FIG. 2 is a schematic diagram illustrating a heat treating reactor used for growing a single crystal Bi nanowire according to an embodiment of the present invention.

As shown in FIG. 2, a heat treating reactor used in an embodiment of the present invention includes a reaction furnace 110 and a quartz tube 150 positioned in the reaction furnace 110 and provided with an alumina boat 130 mounted on the quartz tube 150. In the alumina boat 130, a structure provided with a Bi thin film may be disposed for the growth of a Bi nanowire. In addition, in the reaction furnace 110, a heater is positioned to heat the alumina boat 130. Through the structure thus disposed and the heating in the reaction furnace 110, heat may be applied to the structure including the substrate 10, the oxide layer 30 and the Bi thin film 50 to induce compressive stress.

For example, the Bi thin film has a coefficient of thermal expansion of 13.4×10⁻⁶/° C., the oxide layer (SiO₂) has a coefficient of thermal expansion of 0.5×10⁻⁶/° C., and the substrate (in the case of a Si substrate) has a coefficient of thermal expansion of 2.4×10⁻⁶/° C. Due to the large difference of the coefficients of thermal expansion, compressive stress may be applied to a structure including the substrate 10, the oxide layer 30 and the Bi thin film 50, and a nanowire may be grown on the Bi thin film 50 to relieve the compressive stress. That is, the compressive stress induced by the heat treatment may provide a driving force during the growth of the nanowire.

Meanwhile, the heat treating temperature of the Bi thin film 50 may be preferably 200 to 270° C. in an embodiment of the present invention. In addition, the heat treating time may be to 15 hours. In the case that the heat treating time increases, the Bi thin film expands much more, and more compressive stress may be induced.

Then, as shown in FIG. 1C, a thermoelectric material 70 is sputtered on a nanowire grown on the Bi thin film 50 to manufacture a nanowire having a core/shell structure composed of a Bi nanowire/thermoelectric material.

Generally, a thermoelectric material is a material having thermoelectric properties of Seebeck effect by which a voltage is generated due to temperature difference at both ends and the Peltier effect by which one side generates heat and the other side absorbs heat when current flows between both ends. Particular examples of the thermoelectric material according to an embodiment of the present invention may include one selected from Te, Bi₂Te₃, PbTe, Sb and S.

In an embodiment of the present invention, a sputtering process and a cooling process of the substrate 10 to a low temperature may be performed at the same time. That is, in an embodiment of the present invention, the substrate 10 may be exposed to a cooling medium such as liquid nitrogen during performing the sputtering process so that the substrate 10 may maintain a cool state of a low temperature while sputtering the thermoelectric material 70 on the grown surface of a nanowire. Through the cooling process to the low temperature of the substrate 10, the kinetic energy of the thermoelectric material may be minimized, and the interface roughness between the Bi nanowire and the thermoelectric material of the core/shell structure may be smooth. From the above description, it may be confirmed that the interface roughness may be controlled to a desired level by appropriately controlling the cooling temperature to the low temperature by the cooling process.

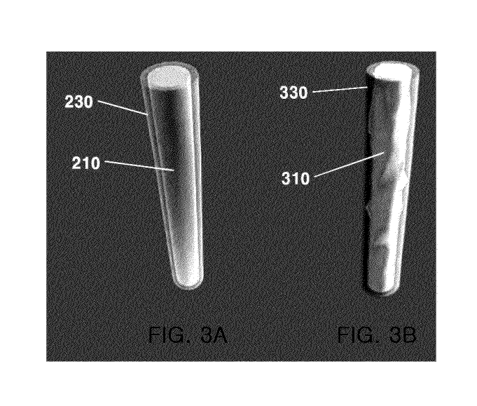

FIGS. 3A and 3B are schematic diagrams for comparing a nanowire having a core/shell structure obtained by performing a low temperature cooling process using liquid nitrogen and a nanowire having a core/shell structure obtained without performing a low temperature cooling process.

As shown in FIG. 3A, a nanowire having a core/shell structure manufactured by performing a low temperature cooling process may be formed to have a smooth interface between the Bi nanowire 210 which may become a core and a thermoelectric material 230 which may become a shell. On the contrary, as shown in FIG. 3B, a nanowire having a core/shell structure manufactured without performing the low temperature cooling process may be formed to have a rough interface between the Bi nanowire 210 which may become a core and a thermoelectric material 230 which may become a shell.

Meanwhile, a final heat treating process of a thermoelectric nanowire having a core/shell structure and produced through the above described processes may be further conducted in an embodiment of the present invention. In an embodiment of the present invention, the final heat treating temperature may be smaller than the melting point of Bi, or may be in the temperature range of the melting point of Bi to the melting point of the thermoelectric material. In the case that the final heat treating temperature is less than the melting point of Bi, the diffusion phenomenon of a material may be generated, and the diffusion of a thermoelectric material such as Te may occur in a Bi core area to produce a BiTe compound. Through this phenomenon, a thermoelectric nanowire having a core/shell structure in which the thermoelectric material is diffused in a core area may be manufactured.

Meanwhile, when the final heat treating temperature is greater than and equal to the melting point of Bi and less than or equal to the melting point of the thermoelectric material, a Bi component may be evaporated, and a nanowire of a thermoelectric material having a tube structure may be synthesized. That is, the tube structure of the thermoelectric material may be synthesized by applying the above-described heat treating temperature, and physical properties of various novel materials such as magnetic Kondo effect may be observed by using the nanowire having the tube structure as well as the thermoelectric properties.

As described above, a thermoelectric nanowire having a core/shell structure including a Bi nanowire manufactured by using compressive stress as a core and a thermoelectric material layer as a shell may be effectively obtained in the present invention.

### MODE FOR INVENTION

Hereinafter, the present invention will be described through various embodiments.

### EXAMPLE 1

A Si substrate provided with a SiO₂ oxide layer formed thereon was prepared, and a Bi thin film was formed on the oxide layer by a RF magnetron sputtering method. In this case, the basic pressure of the sputtering was 4×10⁻⁸ torr, and the forming rate of the Bi thin film was 32.7 Å/s. In addition, during performing the sputtering of the Bi thin film, the substrate was cooled by using liquid nitrogen.

The substrate provided with the Bi thin film formed thereon was mounted on an alumina boat in a reaction furnace as shown in FIG. 2 and heat treated to grow a Bi single crystal nanowire. In this case, a heat treating temperature was 260 to 270° C. and a maintaining time was 10 hours.

Then, a thermoelectric material Te was deposited on the Bi nanowire at room temperature by using a RF magnetron sputtering method. During performing of the sputtering process, the substrate on which the liquid Bi nanowire was grown was cooled to a low temperature. The power of the RF magnetron sputtering was 12 W (rf).

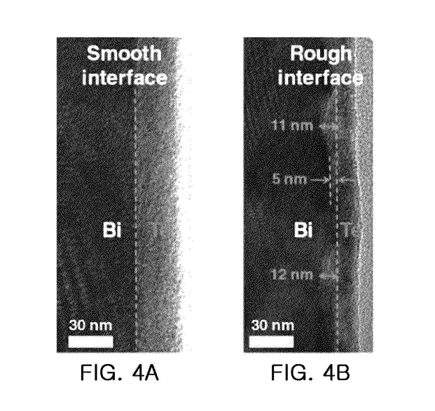

FIG. 4A illustrates a TEM photographic image of a thermoelectric nanowire having a core/shell structure manufactured by the above described method. As shown in FIG. 4A, the interface between the core of the Bi nanowire and the shell of the Te layer is formed smooth with little relative height difference.

### EXAMPLE 2

Bi nanowire was formed as in Example 1, and a thermoelectric material, Te was deposited on the Bi nanowire at room temperature by using a RF magnetron sputtering method. During sputtering, a cooling process with respect to a substrate provided with a liquid Bi nanowire grown thereon to a low temperature was not performed differently from Example 1. The power of the RF magnetron sputtering was 30 W (rf).

FIG. 4B is a TEM photographic image of a thermoelectric nanowire having a core/shell structure manufactured by Example 2. As shown in FIG. 4B, it may be confirmed that the interface between the core of the Bi nanowire and the shell of the Te layer is formed as a rough surface having a height difference of 5 to 12 nm.

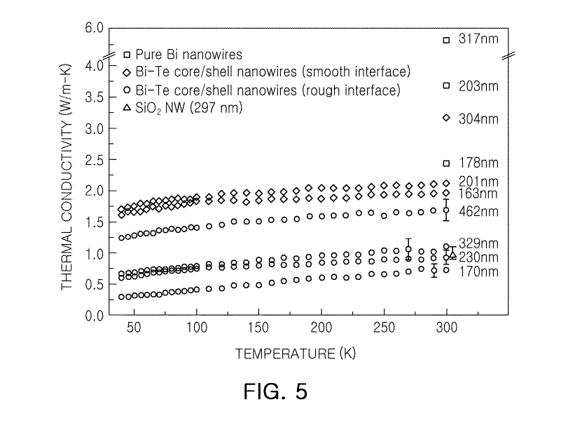

FIG. 5 is a graph illustrating thermal conductivities with respect to the temperature of nanowires having a core/shell structure manufactured by Examples 1 and 2, and a Bi nanowire on which a thermoelectric material is not sputtered. When comparing various nanowires having similar diameters, the Bi nanowire on which a shell structure is not formed has the greatest thermal conductivity. Among the nanowires on which the shell structure is formed, the nanowire manufactured in Example 1 and having a smooth interface has greater thermal conductivity than the nanowire manufactured in Example 2 and having a rough interface. As described above, it may be confirmed that a nanowire having a core/shell structure has smaller thermal conductivity than a pure Bi nanowire. Particularly, the thermal conductivity is dependent on the roughness of the interface between the Bi nanowire and the Te shell. Accordingly, a nanowire having appropriate thermal conductivity in various applications may be manufactured by controlling the roughness of the interface of a core and a shell through controlling the cooling temperature during the sputtering of a thermoelectric material.

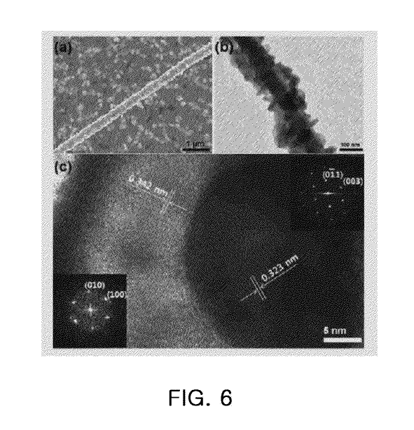

Meanwhile, FIG. 6(a) illustrates a SEM photographic image of a thermoelectric nanowire manufactured in Example 2. Through FIG. 6(a), it may be found that a nanowire grew straight and had a rough surface appropriate for applying as a thermoelectric material. FIG. 6(b) is a TEM photographic image of a single nanowire having a core/shell structure manufactured in Example 2, and a structure having a rough interface between an inner core and a shell may be clearly found. FIG. 6(c) is a HRTEM photographic image of a single nanowire having a core/shell structure manufactured in Example 2, and a single crystal Bi core and a locally single crystal Te shell having defects may be observed. The atomic arrangement at the interface between the core and the shell may be found broken. Thus, the thermal conductivity is expected to decrease.

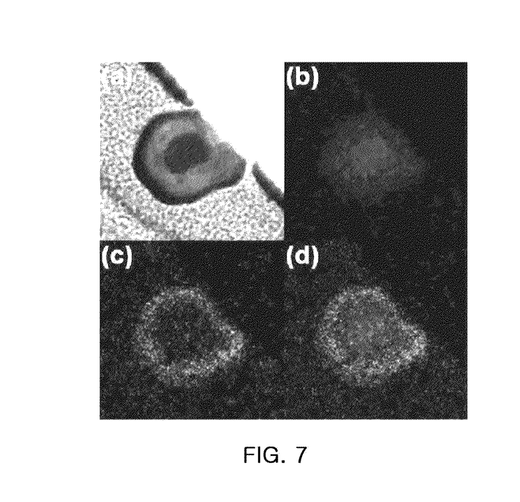

FIG. 7(a) illustrates a TEM photographic image of the cross-section of a thermoelectric nanowire having a core/shell structure manufactured in Example 2. A Bi single crystal nanowire core is found to be surrounded with a shell of a thermoelectric layer. The outer part corresponds to a deposited Pt part. FIGS. 7(b) to 7(d) illustrate element mapping images of the nanowire, and FIG. 7(b) illustrates a Bi element mapping image, FIG. 7(c) illustrates a Te element mapping image, and FIG. 7(d) illustrates a Bi and Te element mapping image. As shown in FIG. 6(d), the thermoelectric nanowire having the core/shell structure is found to be composed of an inner Bi core and a surrounding Te element.

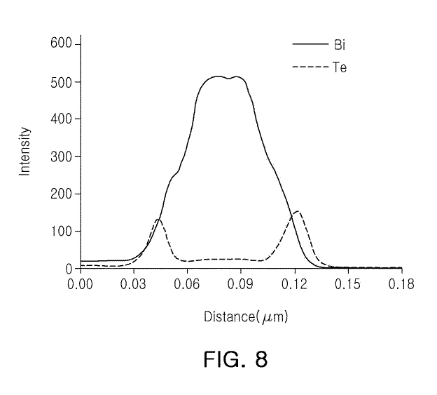

FIG. 8 is a graph illustrating a line scanning image of the cross section of thermoelectric nanowire and shows a core/shell thermoelectric nanowire in which Te surrounds Bi.

### EXAMPLE 3

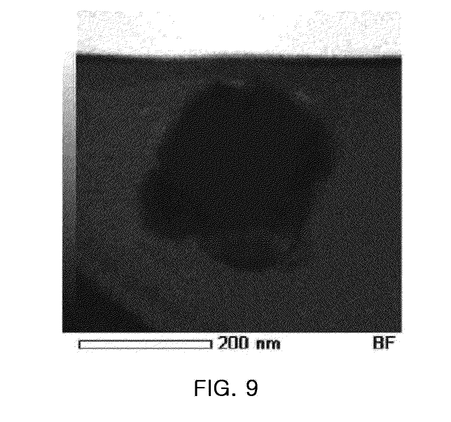

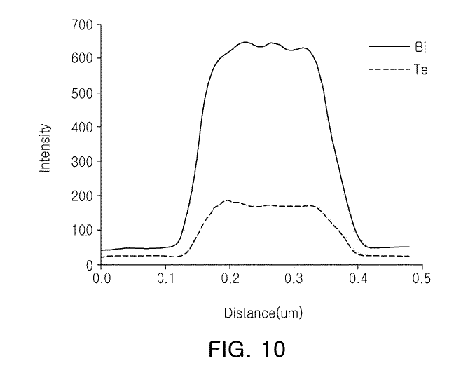

A Bi/Te thermoelectric nanowire having a BiTe compound in a core area and having a core/shell structure was manufactured by finally heat treating a core/shell thermoelectric nanowire manufactured by the same conditions as those in Example 2 to a temperature less than or equal to the melting point of Bi, that is at 250° C. for 2 hours. FIG. 9 illustrates a TEM photographic image illustrated for observing the cross section of a thermoelectric nanowire by depositing Pt by using a Dual Beam apparatus around the thermoelectric nanowire manufactured by the above method, and removing both ends of the necessary cross section of the nanowire to observe the cross section of the nanowire. As shown in FIG. 9, a central circular part (core) and a surrounding part (shell) are observed. FIG. 10 is a graph illustrating a line scanning image of the cross section of a thermoelectric nanowire. Te is diffused in a Bi area to form an alloy, and a thermoelectric nanowire having a core/shell structure may be well suggested on the whole.

### EXAMPLE 4

A Bi/Te thermoelectric nanowire having a core/shell structure was manufactured by the same conditions as those in Example 2. Then, heat treating was performed at the temperature greater than or equal to the melting point of Bi (above 271 degrees) to the temperature less than or equal to the melting point of Te (449 degrees), particularly at 330° C. for 10 hours.

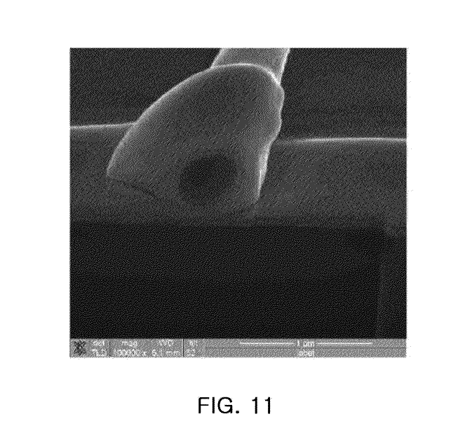

FIG. 11 is a SEM photographic image of a thermoelectric nanowire manufactured through the heat treatment. As shown in FIG. 11, a Bi component may be vaporized through the final heat treatment in the above temperature range, and a Te nanowire having a tube structure on the whole may be manufactured.

### INDUSTRIAL APPLICABILITY

As described above, the manufacturing technique of a core/shell thermoelectric nanowire and an applying technique of a nano device may be confirmed according to the present invention. The improvement of the properties of common devices may be obtained, and the appearance of new devices may be possible.

In addition, since a thermoelectric device using a core/shell thermoelectric nanowire has super-high-efficient thermoelectric effect, a method of developing a new system may be served.

Further, developments to a higher level in various fields such as a Space Generator, a heater, an aeronautical heat regulator, a military infrared detector, and a circuit cooler for missile guidance, may be realized by using the technique of the present invention.

1. A method of manufacturing a thermoelectric nanowire having a core/shell structure, the method comprising:
preparing a substrate provided with an oxide layer formed thereon, and forming a Bi thin film on the oxide layer;
heat treating a structure produced during forming the Bi thin film to induce compressive stress due to differences in coefficients of thermal expansion between the substrate, the oxide layer and the Bi thin film, to grow a Bi single crystal nanowire on the Bi thin film; and
cooling the substrate of a structure on which the nanowire is grown to a low temperature, and sputtering a thermoelectric material on the Bi single crystal nanowire in a cooled state to manufacture a thermoelectric nanowire having a core/shell structure of Bi/thermoelectric material.

2. The method of manufacturing a thermoelectric nanowire having a core/shell structure of claim 1, wherein the manufacturing of the thermoelectric nanowire comprises controlling roughness of an interface between the Bi single crystal nanowire and the thermoelectric material by controlling the temperature for cooling the substrate.

3. The method of manufacturing a thermoelectric nanowire having a core/shell structure of claim 1, wherein the cooling to a low temperature is performed by using liquid nitrogen.

4. The method of manufacturing a thermoelectric nanowire having a core/shell structure of claim 1, wherein the forming of the Bi thin film comprises forming the Bi thin film on the oxide layer in the cooled state using a sputtering method.

5. The method of manufacturing a thermoelectric nanowire having a core/shell structure of claim 1, wherein the thermoelectric material is one selected from Te, Bi₂Te₃, PbTe, Sb and S.

6. The method of manufacturing a thermoelectric nanowire having a core/shell structure of claim 1, wherein the single crystal Bi nanowire has a diameter of 50 to 1,000 nm.

7. The method of manufacturing a thermoelectric nanowire having a core/shell structure of claim 1, wherein the oxide layer is at least one selected from the group consisting of SiO₂, BeO, and Mg₂Al₄Si₅O₁₈.

8. The method of manufacturing a thermoelectric nanowire having a core/shell structure of claim 1, wherein the heat treating temperature is 200 to 270° C.

9. The method of manufacturing a thermoelectric nanowire having a core/shell structure of claim 1, further comprising final heat treating the core/shell thermoelectric nanowire thus manufactured in the manufacturing operation of the thermoelectric nanowire.

10. The method of manufacturing a thermoelectric nanowire having a core/shell structure of claim 9, wherein a temperature of the final heat treating is selected from a temperature less than or equal to a melting point of Bi, or a temperature greater than or equal to a melting point of Bi to a temperature less than or equal to a melting point of the thermoelectric material.

11. The method of manufacturing a thermoelectric nanowire having a core/shell structure of claim 2, wherein the cooling to a low temperature is performed by using liquid nitrogen.
